(19) United States
(12) Patent Application Publication
(10) Pub. No.: US 2016/0053368 A1
(43) Pub. Date: Feb. 25, 2016

(54) DEPOSITION FILM FORMING APPARATUS INCLUDING ROTARY MEMBER

(71) Applicant: TGO Tech. Corporation, Hwaseong-si (KR)

(72) Inventors: Yoojin LEE, Yongin-si (KR); Jaehak LEE, Seoul (KR)

(21) Appl. No.: 14/635,161

(22) Filed: Mar. 2, 2015

(30) Foreign Application Priority Data
Jan. 6, 2014 (KR) 10-2014-0001455

(51) Int. Cl. C23C 14/50; C30B 35/00; C30B 25/12; C23C 16/458; C30B 23/02

(52) U.S. Cl. CPC C23C 14/505; C23C 16/4584; C30B 23/025; C30B 25/12; C30B 35/005

(57) ABSTRACT

Disclosed is a deposition film forming apparatus including a plurality of rotary members. The deposition film forming apparatus includes a plurality of rotary members arranged on each substrate support in which the plurality of rotary members are configured to rotate a plurality of substrates, respectively. Each of the rotary members is rotated on the substrate support by a gas-foil method, and a cover is provided on a portion on the substrate support, other than portions where the plurality of rotary members are positioned. A gap is formed between the substrate supports and the cover to allow a predetermined gas used in the gas foil method to be discharged therethrough.

### BACKGROUND

1. Field

The present invention relates to a deposition film forming apparatus including a rotary member. In particular, the present invention relates to a deposition film forming apparatus in which rotation of a substrate is capable of being controlled by a rotary member included in each of a plurality of substrate support.

2. Description of the Related Art

A Light Emitting Diode (LED) is a semiconductor light-emitting element which converts a current to light and has been widely used as a light source for a display image of an electronic device including data communication equipment. In particular, as it has been known that unlike a conventional light, such as an incandescent lamp or a fluorescent lamp, such an LED is excellent in efficiency of converting electric energy into light energy to save energy up to 90%, the LED is widely in the limelight as an element which can substitute the fluorescent lamp or the incandescent lamp.

A manufacturing process of such an LED element may be generally divided into an epitaxial process, a chip process, and a package process. The epitaxial process refers to a process of epitaxially growing a compound semiconductor on a substrate, the chip process refers to a process of forming an electrode at respective portions of the epitaxially grown substrate to fabricate an epitaxial chip, and the package process refers to a process of connecting a lead to the epitaxial chip fabricated as described above and packaging the epitaxial chip such that light can be emitted to the outside as much as possible.

Among such processes, the epitaxial process may be referred to as the most salient process to be decisive of the light emitting efficiency of the LED element. This is due to the fact that when the compound semiconductor is not epitaxially grown on the substrate, a defect may occur within a crystal and the defect acts as a non-radiative center, deteriorating the light emitting efficiency of the LED element.

In such an epitaxial process, i.e. the process of forming an epitaxial layer on a substrate, for example, a Liquid Phase Epitaxy (LPE) method, a Vapor Phase Epitaxy (VPE) method, a Molecular Beam Epitaxy (MBE) method, or a Chemical Vapor Deposition (CVD) method is used. Among others, a Metal-Organic Chemical Vapor Deposition (MOCVD) method or a Hydride Vapor Phase Epitaxy (HVPE) is mainly used.

When an epitaxial layer is formed on a plurality of substrates using the conventional MOCVD method or HVPE method, a process gas for processing the substrates within a chamber is conventionally supplied. In order to enhance uniformness of processes, it is preferable that a substrate support, on which the plurality of substrates are seated, revolves. Further, it is also preferable that each of the plurality of substrates rotates on the substrate support. However, it is difficult to configure a conventional deposition film forming apparatus such that the substrate support revolves while each of the plurality of substrates rotates.

### SUMMARY

The present invention has been made to solve the above-described problems in the related art, and an object of the present invention is to provide a deposition film forming apparatus in which a rotation of a substrate may be controlled by a rotary member which is included in each of a plurality of substrate supports.

According to an embodiment, there is provided a deposition film forming apparatus including a plurality of substrate supports. A plurality of rotary members are arranged on each of the substrate support in which the plurality of rotary members are configured to rotate a plurality of substrates, respectively. Each of the rotary members is rotated on the substrate support by means of a gas-foil method, and a cover is provided on a portion on the substrate support, except where the plurality of rotary members are positioned. A gap is formed between the substrate supports and the cover to allow a predetermined gas used in the gas-foil method to be discharged therethrough.

According to the present invention, there is provided a deposition film forming apparatus in which a rotation of a substrate may be controlled by a rotary member which is included in each of a plurality of substrate supports.

In addition, according to the present invention, there is provided a deposition film forming apparatus which may improve uniformness of a deposition film between a plurality of substrates.

### BRIEF DESCRIPTION OF THE DRAWINGS

The above and other objects, features and advantages of the present invention will be more apparent from the following detailed description taken in conjunction with the accompanying drawings, in which:

FIG. 1 is a view illustrating a configuration of a deposition film forming apparatus according to an embodiment of the present invention;

FIG. 2 is a plan view illustrating a configuration of a substrate support according to an embodiment of the present invention;

FIG. 3 is a vertical cross-sectional view illustrating a part of the configuration of the substrate support according to the embodiment of the present invention;

FIG. 4 is a plan view illustrating the configuration of the substrate support from which rotary members and a cover are removed;

FIG. 5 is a perspective view illustrating the configuration of the substrate unit 30 of FIG. 4 which is viewed at a different angle;

FIG. 6 is a view illustrating a part of the configuration of the deposition film forming apparatus 10 according to the embodiment of the present invention;

FIG. 7 is an enlarged view illustrating the “B” portion in FIG. 6;

FIG. 8 is a view illustrating a configuration of a first support according to an embodiment of the present invention;

FIG. 9 is a view illustrating a part of a substrate support according to another embodiment of the present invention; and

FIG. 10 is a view illustrating a coupling structure between a connection tube and a substrate support according to another embodiment of the present invention.

### DETAILED DESCRIPTION

The detailed description of the present disclosure will be given below with reference to the accompanying drawings illustrated for specific embodiments implementing the present disclosure as examples. The embodiments will be sufficiently described in detail such that those skilled in the art may carry out the present disclosure. It should be understood that although various embodiments of the present invention are different from each other, they need not be mutually exclusive. For example, in regard to an embodiment, specific forms, structures, and characteristics described herein may be realized through another embodiment without departing from the spirit and scope of the present invention. Moreover, it should be understood that locations or arrangements of separate elements within the disclosed embodiments can be changed without departing from the spirit and scope of the present invention. Accordingly, the detailed descriptions which will be given below are not intended to be restrictive, and the scope of the present disclosure, if properly described, should be limited only by the accompanying claims and equivalents thereof. Similar reference numerals shown in the drawings denote members performing an identical or similar function in several aspects.

Hereinafter, a configuration of the present invention will be described in detail with reference to the accompanying drawings.

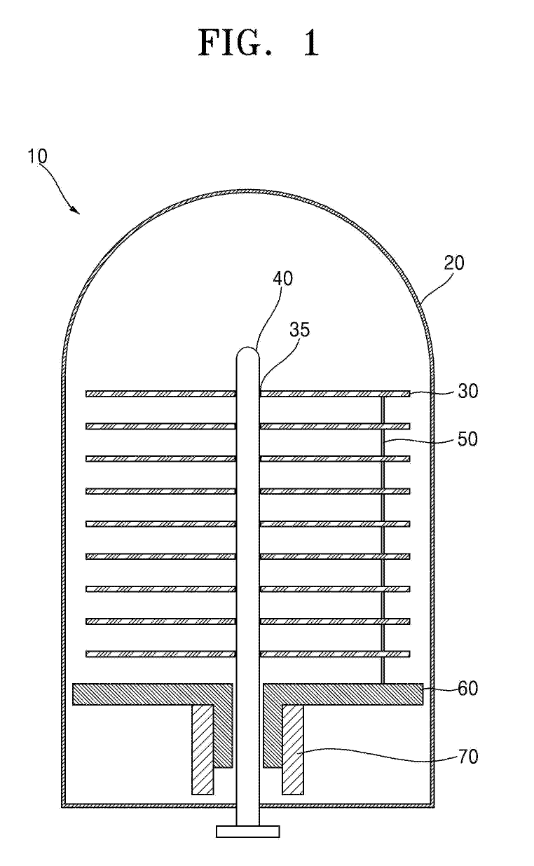

FIG. 1 is a view illustrating a configuration of a deposition film forming apparatus according to an embodiment of the present invention.

First, the material of a substrate (not illustrated) loaded in a deposition film forming apparatus 10 is not particularly limited, and substrates of various materials, such as glass, plastic, polymer, silicon wafer, stainless steel, and sapphire, may be loaded. Hereinafter, descriptions will be made assuming a circular sapphire substrate used in the light emitting diode field.

The deposition film forming apparatus 10 according to an embodiment of the present invention may include a chamber 20. The chamber 20 is configured such that the internal space thereof is substantially sealed while a process is performed in the internal space, and may conduct a function of providing a space in which a deposition film is formed on a plurality of substrates. Such a chamber 20 is configured to maintain an optimum process condition, and may be configured in a rectangular shape or a circular shape. The chamber 20 is preferably made of a quartz glass or graphite coated with silicon carbonate (SiC) but is not limited thereto.

In general, a process for forming a deposition film on a substrate is performed by supplying a deposition material to the inside of the chamber 20 and heating the inside of the chamber 20 to a predetermined temperature (e.g., about 800° C. to 1,200° C.). The deposition material supplied as such is supplied to the substrate to play a part in the formation of the deposition film.

According to the embodiment of the present invention, the deposition film forming apparatus 10 may include a heater (not illustrated). The heater may be installed on the outside of the chamber 20 to conduct a function of applying heat required for the deposition process to a plurality of substrates. In order to facilitate the growth of the deposition film, the heater may heat the substrates to a temperature of about 1200° C. or higher.

According to the embodiment of the present invention, the deposition film forming apparatus 10 may include a substrate support 30. Preferably, a plurality of substrate supports 30 may be provided in the deposition film forming apparatus 10 and arranged and installed in a plurality of tiers. When the plurality of substrate supports 30 are provided, the plurality of substrate support 30 may be arranged and fixed to be spaced apart from each other by a predetermined space therebetween by space maintaining members (not illustrated). The number of the substrate supports 30 may be variously changed according to a purpose of using the present invention. The substrate supports 30 and the space maintaining members are preferably made of a quartz glass but are not limited thereto.

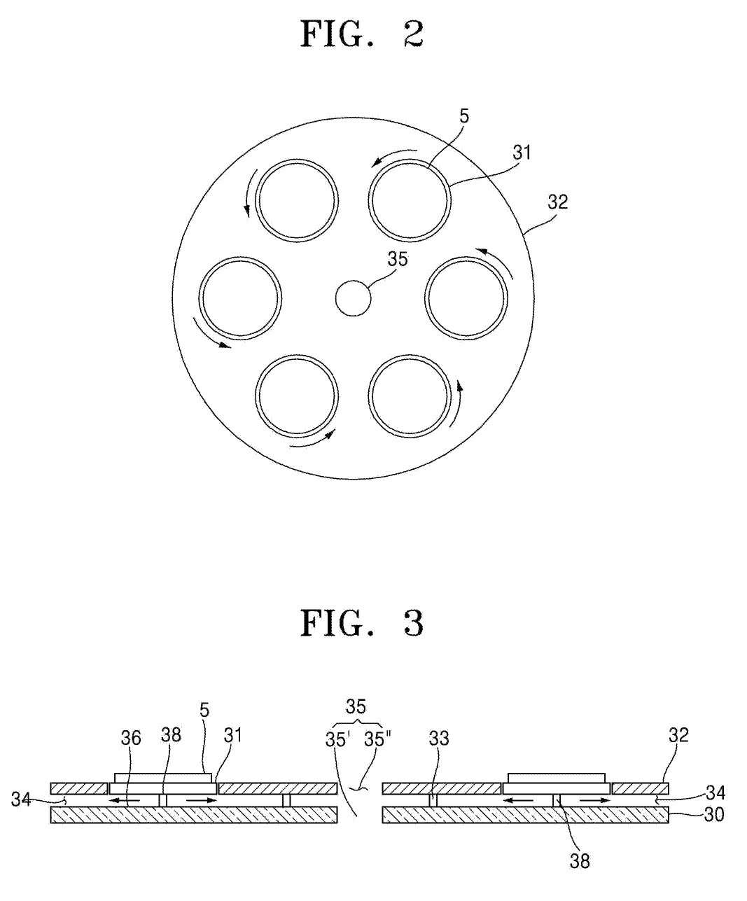

In addition, a plurality of rotary members 31 (see FIG. 2) may be installed on each of the substrate supports 30. The number of rotary members 31 installed on each substrate support 30 is preferably equal to the number of substrates mounted on each substrate support 30 but is not necessarily limited thereto. In order to ensure that a substrate processing gas is uniformly supplied to the substrates, the rotary members 31 may have a function of rotating the substrates. A detailed configuration related to this will be described later.

According to an embodiment of the present invention, the deposition film forming apparatus 10 may include the process gas supply unit 40. The process gas supply unit 40 may perform a function of supplying the substrate processing gas required for forming the deposition film to the inside of the chamber 20.

Herein, it is described that the process gas supply unit 40 is arranged at the center of the chamber 20 but is not limited thereto.

In an embodiment of the present invention, the deposition film forming apparatus 10 may include a first support 60. The first support 60 may be installed below the chamber 20 to support the plurality of substrate supports 30 while the deposition process is performed. In addition, when the first support 60 is rotated by a separate rotating apparatus (not illustrated), a function of causing the plurality of substrate supports 30 to be revolved may be performed.

According to an embodiment of the present invention, the deposition film forming apparatus 10 may include a second support 70. The second support 70 may be installed below the chamber 20 together with the first support 60 to enclose the outer periphery of the first support 60. In addition, the second support 70 may be installed to be fixed in relation to the chamber 20 despite the rotation of the first support 60.

Hereinafter, a configuration of the substrate support 30 according to an embodiment of the present invention will be described in more detail.

FIG. 2 is a plan view illustrating a configuration of a substrate support 30 according to an embodiment of the present invention, and FIG. 3 is a vertical cross-sectional view illustrating the configuration of the substrate support 30 according to the embodiment of the present invention.

Referring to FIGS. 2 and 3, according to an embodiment of the present invention, the substrate support 30 may include a plurality of rotary members 31 such that a plurality of substrates 5 may be seated thereon. Each rotary member 31 may have a shape corresponding to that of a substrate, for example, a circular shape. Each of the plurality of rotary members 31 may be rotated on the substrate support 30 by a gas-foil method. Although the present embodiment illustrates that the number of substrates 5 seated on the substrate support 30 is six (6), but is not limited thereto, and the positions where the substrates are seated on the substrate support 30 may also be changed.

In addition, a portion of the substrate support 30, other than the portions where the rotary members 31 are disposed, may be covered with a separate cover 32. The rotary members 31 and the cover 32 may be installed such that the top surfaces of the rotary members 31 have substantially the same height as the top surface of the cover 32.

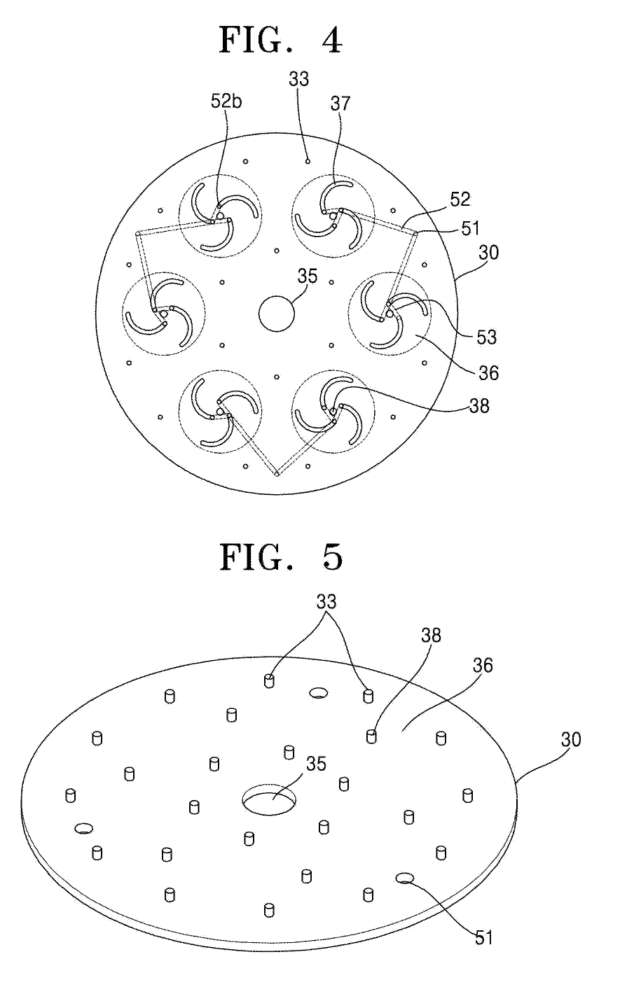

Hereinafter, referring to FIGS. 4 and 5, descriptions will be made on flow channels 51, 52, and 53 and grooves 37 to which a predetermined gas is supplied within the substrate support 30. FIG. 4 is a plan view illustrating the configuration of the substrate support 30 from which rotary members 31 and a cover 32 are removed, and FIG. 5 is a perspective view illustrating the configuration of the substrate unit 30 of FIG. 4 which is viewed at a different angle.

Referring to FIGS. 4 and 5, rotary member accommodation portions 36 that correspond to the rotary members 31 may be defined at the positions where the rotary members 31 are disposed in the substrate support 30. The grooves 37 may be formed on each of the rotary member accommodation portions 36. A predetermined gas (e.g., N₂ gas) may flow in the grooves 37. The predetermined gas may be supplied from first flow channels 51 through second flow channels 52 and third flow channels 53 to the grooves 37. The flow of the predetermined gas in the grooves 37 may provide a rotational force to rotate each of the rotary members 31. The grooves 37 may be shaped to rotate the rotary members 31 in a predetermined direction. For example, each of the grooves 37 may be formed in a spiral shape in a predetermined direction. Also, in order to adjust the number of revolutions of the rotary members 31, the width or depth of the grooves 37 may be adjusted. In addition, although FIG. 4 illustrates that the width and depth of the grooves 37 are constant along the flowing direction of the predetermined gas, the width and depth of the grooves 37 may be continuously changed along to the flowing direction of the predetermined gas. Along the flowing direction of the predetermined gas, for example, the width of the grooves 37 may be gradually narrowed and the depth of the grooves 37 may be gradually reduced.

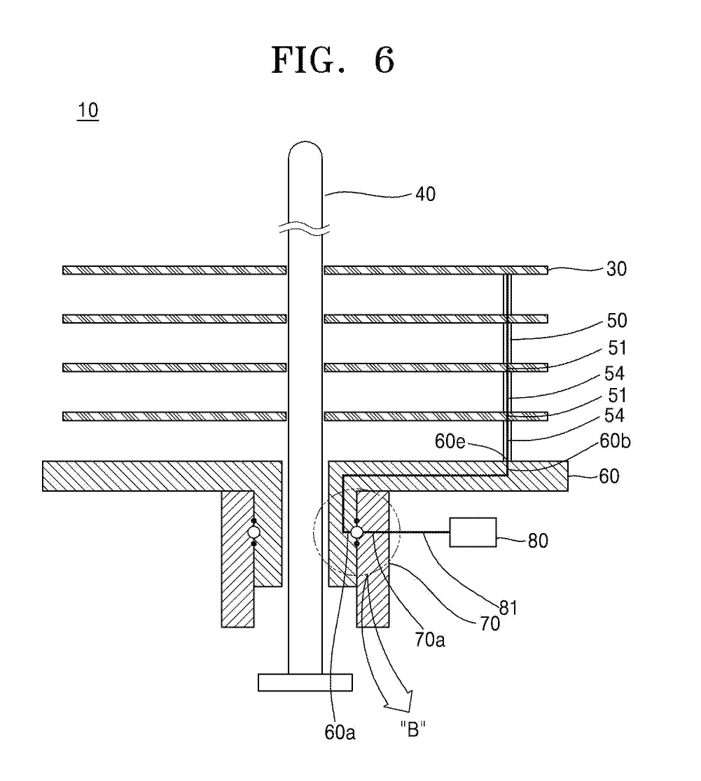

One end of each of the second flow channels 52 may be connected with a first flow channel 51. A predetermined gas supplied from a gas supply unit 80 (see FIG. 6), which will be described later, may flow in the first flow channel 51. Although FIG. 4 illustrates that three first flow channels 51 are formed in the substrate support 30, and two second flow channels 52 are branched from each of the first flow channels 51, the number of the first flow channels 51 and the number of the second flow channels 52 branched from each of the first flow channels 51 are not limited thereto, and the number of the flow channels may increase. Furthermore, although it is illustrated that the third flow channels 53 are branched from the middle of the second flow channels 52, the present invention is not limited thereto, and the way the flow channels are arranged may be changed if necessary. Although the positions where the first flow channels 51 are formed are depicted outside of the substrate support 30 in the drawing, the present invention is not limited thereto, and the first channels 51 may be formed at any position as long as the object of the present invention may be achieved.

In addition, in order to prevent deviation in rotational velocities between the rotary members 31, it is preferable that the same amount of the predetermined gas is supplied to each of the second flow channels 52. For this purpose, it is preferable that the sum total of the cross-sectional areas of the plurality of first flow channels 51 is greater than the sum total of the cross-sectional areas of the plurality of second flow channels 52.

A protrusion 38 is formed at the center of each of the rotary member accommodation portions 36 to be engaged with a recess (not illustrated) that is formed at the center of the bottom surface of each rotary member 31. As the protrusions 38 are engaged with the recesses of the rotary members 31, respectively, and the predetermined gas flows in the grooves 37, the rotary members 31 may be rotated around the protrusions 38, respectively.

Hereinafter, gap formation members 33 will be described with reference to FIGS. 3 and 5. If the cover 32 is in close contact with the substrate supports 30, a predetermined gas supplied to the grooves 37 in order to rotate the rotary members 31 may not be smoothly discharged and may produce turbulence below the rotary members 31, thereby interfering with the rotation of the rotary members 31 or being leaked between the rotary members 31 and the cover 32 to hinder deposit formation on the substrates 5. Accordingly, a plurality of gap formation members 33 may be provided on the substrate supports 30. A gap 34 may be formed by the gap formation members 33 between the cover 32 and the substrate support 30 to ensure that the predetermined gas may be smoothly discharged. Since the predetermined gas supplied to the grooves 37 so as to rotate the rotary members 31 may be smoothly discharged through the gap 34, it is possible to solve the problems of the turbulence being produced below the rotary members 31 to interfere with the rotation of the rotary members 31 and the formation of deposit on the substrates 5 being hindered.

Furthermore, a central through-hole 35 may be formed at the center of the substrate support 30 and at the center of the cover 32 so that a process gas supply unit 40 penetrates the substrate support 30 and the cover 32. The central through-hole 35 may include a first central through-hole 35′ formed through the substrate support 30 and a second central through-hole 35″ formed through the cover 32. It would be preferable that the diameter of the central through-hole 35 is somewhat greater than that of the process gas supply unit 40.

Hereinafter, a method of supplying the predetermined gas for rotating the rotary members 31 to the substrate support 30 will be described with reference to FIGS. 6 to 8.

FIG. 6 is a view illustrating a part of the configuration of the deposition film forming apparatus according to the embodiment of the present invention;

Referring to FIG. 6, according to an embodiment of the present invention, the deposition film forming apparatus 10 may include a gas supply unit 80. The gas supply unit 80 may supply a predetermined gas (for example, N₂ gas) to the inside of the second support 70 through a gas supply path 81.

An internal supply path 70a may be formed within the second support 70 so as to provide a path in which the predetermined gas may flow. The predetermined gas that flows in the internal supply path 70a flows to the inside of a connection flow channel 54 formed inside a connection tube 50 through the internal flow channel 60a formed within the first support 60 and connected with the internal supply path 70a, and through an outlet 60e which is connected to the connection tube 50. The connection flow channel 54 interconnects the plurality of substrate supports 30 so that the predetermined gas may be supplied to the uppermost substrate support 30. Each of the substrate supports 30 is provided with the first flow channels 51 so that the predetermined gas may be supplied to the second flow channels 52 and the third flow channels 53, as described above.

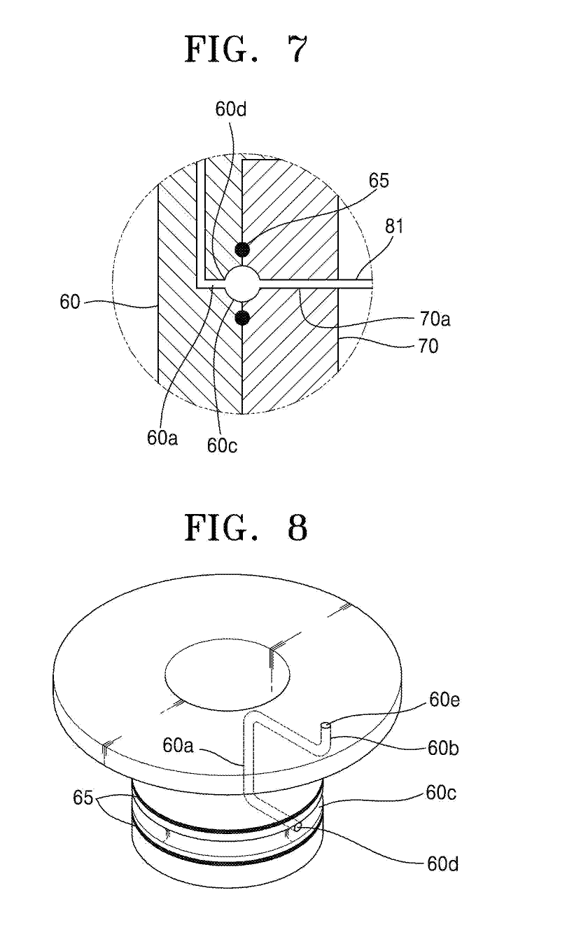

FIG. 7 is an enlarged view illustrating the “B” portion in FIG. 6. The “B” portion is a portion related to a path through which the predetermined gas flows from the second support 70 to the first support 60. Furthermore, FIG. 8 is a view illustrating a configuration of a first support according to an embodiment of the present invention.

Referring to FIGS. 7 and 8, a connection portion 60c may be formed at the first support 60 between the internal supply path 70a and the internal flow channel 60a. The connection portion 60c may be formed in a concave ring shape on an outer surface of the first support 60 along the rotation direction of the first support 60. Accordingly, even if the first support 60 rotates, the predetermined gas supplied from the internal supply path 70a may flow into the internal flow channel 60a within the first support 60.

An inlet 60d, from which the internal flow channel 60a starts, may be formed at a predetermined position in the connection portion 60c. Since the first support 60 is rotatable, the position of the inlet 60d may rotate. Accordingly, even if the positions of the internal supply path 70a and the inlet 60d do not correspond to each other, the predetermined gas discharged from the internal flow channel 60a may flow along the connection portion 60c of the concave ring shape and then flow into the inlet 60d. Sealing members 65 may be arranged along the upper and lower portions of the connection portion 60c, thereby preventing the predetermined gas from leaking to the outside between the first support 60 and the second support 70.

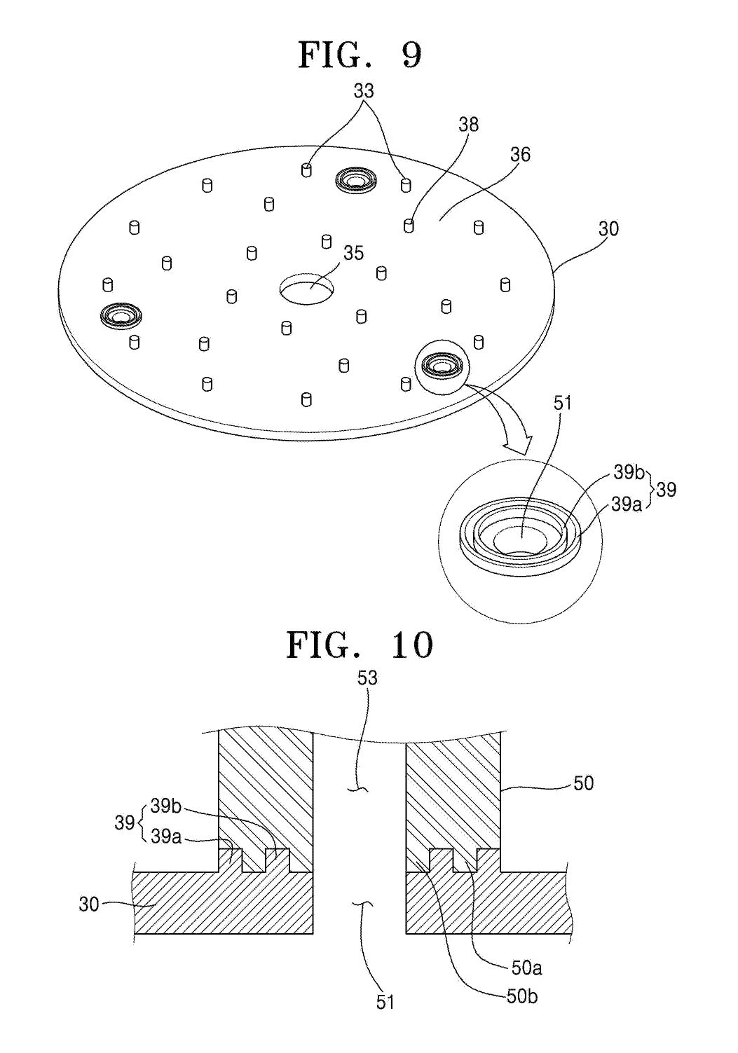

According to another embodiment of the present invention, there is provided a coupling structure between a connection tube 50 and the substrate support 30 so as to prevent leakage of the predetermined gas between the connection tube 50 and the substrate support 30. FIG. 9 is a view illustrating a part of a substrate support according to another embodiment, and FIG. 10 is a view illustrating a coupling structure between a connection tube and a substrate support according to another embodiment of the present invention.

Referring to FIGS. 9 and 10, a coupling member 39 having a -concave-convex shape may be formed around an area where each connection tube 50 is coupled to the substrate support 30, i.e., around a position where each of the first flow channels 51 is formed. The coupling member 39 may consist of a first coupling member 39a that is formed in the outer portion and a second coupling member 39b that is formed in the inner portion. Each of the first and second members 39a and 39b may be formed in a ring shape. Correspondingly, a configuration having a concave-convex structure that corresponds to the concave-convex shape of the coupling member 39, i.e., a first counterpart coupling member 50a and a second counterpart coupling member 50b may be formed at the end of each connection tube 50. As illustrated in FIG. 10, when the connection tube 50 and the substrate support 30 are coupled to each other, the first counterpart coupling 50a may be inserted between the first coupling member 39a and the second coupling member 39b, and the second counterpart coupling member 50b may be inserted into the inside of the second coupling member 39b. That is, the concave-convex shape formed at the end of the connection tube 50 and the concave-convex shape of the coupling member 39 may be engaged with each other. By the method of coupling the connection tube 50 and the substrate support 30, leakage of the predetermined gas between the connection tube 50 and the substrate support 30 may be prevented.

Although the coupling structure between the coupling tube 50 and the substrate support 30 has been described above, the same coupling structure may also be applied when the connection tube 50 is coupled with the first support 60.

The present invention has been illustrated and described above with reference to embodiments. However, the present invention is not limited to the embodiments and various modifications and changes may be made by a person ordinarily skilled in the art to which the present invention belongs without departing from a spirit of the present invention. Such modifications and changes shall be considered as belonging to the scope of the present invention which is defined by the accompanying claims.

What is claimed is:

1. A deposition film forming apparatus, the apparatus comprising:
a plurality of substrate supports,
wherein a plurality of rotary members are arranged on each of the substrate supports, the plurality of rotary members being configured to rotate a plurality of substrates, respectively,
each of the rotary members is rotated on the substrate support by means of a gas-foil method,
a cover is provided on a portion on the substrate support, except where the plurality of rotary members are positioned, and
a gap is formed between the substrate supports and the cover to allow a predetermined gas used in the gas-foil method to be discharged therethrough.

2. The apparatus of claim 1, wherein each of the plurality of substrate supports is configured to be rotatable.

3. The apparatus of claim 1, wherein top surfaces of the plurality of rotary members have the same height as top surface of the cover.

4. The apparatus of claim 1, wherein a plurality of gap formation members are disposed on the substrate supports to form a gap between the substrate supports and the cover.

5. The apparatus of claim 1, wherein a protrusion is formed in each of a plurality of portions on the substrate support where the plurality of rotary members are positioned, and
each of the plurality of rotary members are configured to rotate about the protrusion.

6. The apparatus of claim 2, further comprising:
first and second supports configured to support the plurality of substrate supports,
wherein the first support is configured to be rotatable together with the plurality of substrate supports, and the second support is fixed.

7. The apparatus of claim 6, wherein an internal supply path is formed in the second support to convey a predetermined gas,
an internal flow channel is formed in the first support to convey the predetermined gas to the plurality of substrate supports, and
a connection portion of a concave ring shape is formed on a lateral surface of the first support to interconnect the internal supply path and the internal flow channel.

8. The apparatus of claim 7, wherein a sealing member is formed in at least one of an upper portion and a lower portion of the connection portion to prevent leakage of the predetermined gas.

9. The apparatus of claim 7, wherein at least one connection tube configured to allow the predetermined gas to flow therethrough is provided between the first support and a substrate support positioned lowest among the plurality of substrate supports and/or between adjacent substrate supports.

10. The apparatus of claim 9, wherein a coupling member configured to prevent leakage of the predetermined gas is formed on the first support or a portion coupled to the connection tube on each of the plurality of substrate supports.

11. The apparatus of claim 10, wherein the coupling member has a concave-convex shape.

12. The apparatus of claim 11, wherein an end of the connection tube is formed with a concave-convex shape that corresponds to the concave-convex shape of the coupling member, and
the concave-convex shape formed on the end of the connection tube and the concave-convex shape of the coupling member are engaged with each other.
